(19) United States
(12) Patent Application Publication
(10) Pub. No.: US 2026/0173596 A1
(43) Pub. Date: Jun. 18, 2026

(54) SEMICONDUCTOR LIGHT-EMITTING DEVICE AND LIGHT-EMITTING APPARATUS INCLUDING THE SAME

(71) Applicant: Xiamen San'An Optoelectronics Co., Ltd., Xiamen (CN)

(72) Inventors: Qing WANG, Xiamen (CN); Quanyang MA, Xiamen (CN); Dazhong CHEN, Xiamen (CN); Gong CHEN, Xiamen (CN); Ling-yuan HONG, Xiamen (CN); Kang-Wei PENG, Xiamen (CN); Su-hui LIN, Xiamen (CN)

(21) Appl. No.: 19/463,602

(22) Filed: Jan. 29, 2026

Related U.S. Application Data
(63) Continuation of application No. 18/164,232, filed on Feb. 3, 2023.
Application No. 18/164,232 is a continuation-in-part of application No. PCT/CN2020/108900, filed on Aug. 13, 2020.

(51) Int. Cl. H10H 20/84; H10H 20/854

(52) U.S. Cl. CPC H10H 20/84; H10H 20/854

(57) ABSTRACT

A semiconductor light-emitting device includes a semiconductor light-emitting stack and an insulating light-transmissive layer. The semiconductor light-emitting stack includes an active layer and has a light-emitting surface. The insulating light-transmissive layer is disposed on the light-emitting surface and includes a base and a grade index structure. The base has a first refractive index. The grade index structure is disposed on the base in a way that the base is disposed between the semiconductor light-emitting stack and the graded index structure. The graded index structure includes at least two films and has a gradually varying refractive index which gradually decrease in a direction away from the base, and which is greater than the first refractive index. A light-emitting apparatus including the semiconductor light-emitting device and a sealing resin is also provided.

### CROSS-REFERENCE TO RELATED APPLICATION

This is a continuation application of U.S. patent application Ser. No. 18/164,232, filed on Feb. 3, 2023, which is a bypass continuation-in-part (CIP) application of PCT International Application No. PCT/CN2020/108900, filed on Aug. 13, 2020. The aforesaid applications are incorporated by reference herein in their entirety.

### FIELD

The disclosure relates to a semiconductor device and an apparatus including the same, and more particularly to a semiconductor light-emitting device and a light-emitting apparatus including the same.

### BACKGROUND

Semiconductor light-emitting devices, also known as light-emitting diodes (LEDs), are commonly used light emitters that release energy via electron-hole recombination. Furthermore, they are widely applied in the field of illumination. The LEDs may effectively convert electrical energy into light energy, and have been broadly employed in modern society in fields such as lighting, tablet display, and medical devices.

A conventional LED may be of a face-up type, a flip-chip type, or a vertical type, wherein both of the face-up type and the vertical type emit light through a front surface provided by a semiconductor light-emitting stack while the flip-chip type emits light through a surface provided by a substrate. In addition, in both of the face-up type and the vertical type, the front surface of the semiconductor light-emitting stack is formed with a P-electrode and an N-electrode, and the front surface of the semiconductor light-emitting stack exposed from the electrodes is covered by an insulating light-transmissive layer. When light radiated from an interior of the semiconductor light-emitting stack reaches the front surface, it needs to pass through the insulating light-transmissive layer first in order to be emitted out of the LED. The light transmittance of the insulating light-transmissive layer may affect the light emission efficiency of the LED. Moreover, if the LED is sealed using silicone or epoxy resin to form a package, the impact on light extraction at an interface between the insulating light-transmissive layer and the silicone or the epoxy resin needs to be further taken into consideration.

Previously, the insulating light-transmissive layer of the face-up type or the vertical type is a single layer of silicon dioxide (SiO₂) film. The silicon dioxide film only serves to prevent exposure of the active layer from a side surface of a chip, but offers no help in transmission of light emitted from the interior of the LED through the front surface, further limiting the light emission efficiency of the LED.

### SUMMARY

Therefore, an object of the disclosure is to provide a semiconductor light-emitting device and a light-emitting apparatus that can alleviate at least one of the drawbacks of the prior art.

According to a first aspect of the disclosure, the semiconductor light-emitting device includes a semiconductor light-emitting stack and an insulating light-transmissive layer. The semiconductor light-emitting stack includes an active layer and has a light-emitting surface. The insulating light-transmissive layer is disposed on the light-emitting surface and includes a base and a graded index structure. The base has a first refractive index. The graded index structure is disposed on the base in a way that the base is disposed between the semiconductor light-emitting stack and the graded index structure. The graded index structure includes at least two films and has a gradually varying refractive index which gradually decreases in a direction away from the base, and which is greater than the first refractive index.

According to a second aspect of the disclosure, the semiconductor light-emitting device includes a semiconductor light-emitting stack and an insulating light-transmissive layer. The semiconductor light-emitting stack includes an active layer and has a light-emitting surface. The insulating light-transmissive layer is disposed on the light-emitting surface, and includes a base and a graded index structure. The base is a nitrogen-free film. The graded index structure is disposed on the base, and includes at least two films. The graded index structure has a gradually varying refractive index which gradually decreases in a direction away from the base. The at least two films include a first film which is in contact with the base and which is a nitride film.

According a third aspect of the disclosure, the light-emitting apparatus includes the semiconductor light-emitting device and a sealing resin.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional view illustrating a first embodiment of a semiconductor light-emitting device according to the disclosure.

FIG. 2 is a top view illustrating the first embodiment of the semiconductor light-emitting device according to the disclosure.

FIG. 3 is a schematic view illustrating an insulating light-transmissive layer and a transparent conductive layer of the first embodiment of the semiconductor light-emitting device according to the disclosure.

FIG. 4 is a cross-sectional view illustrating a light-emitting apparatus which is obtained after sealing the first embodiment of the semiconductor light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

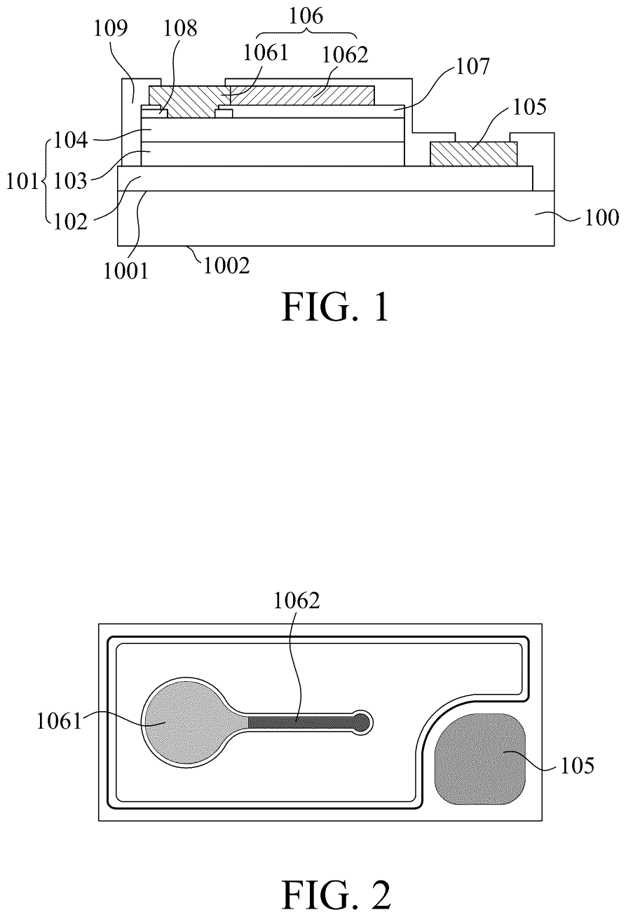

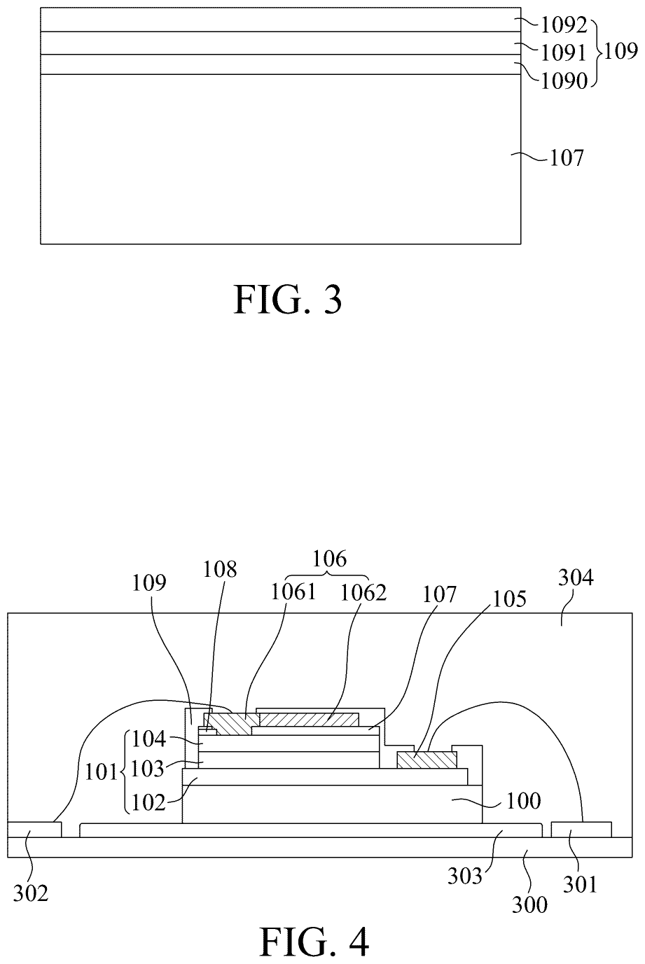

Referring to FIGS. 1 to 2, a first embodiment of a semiconductor light-emitting device according to the disclosure includes a substrate 100, a semiconductor light-emitting stack 101, a transparent conductive layer 107, a first electrode 105, and a second electrode 106. In this embodiment, the semiconductor light-emitting device is a face-up light-emitting device.

The substrate 100 is transparent, and may be, for example, a sapphire substrate, a glass substrate, or other substrate of transparent material. The substrate 100 includes a first surface 1001 and a second surface 1002. The first surface 1001 of the substrate 100 may include a pattern, on which the semiconductor light-emitting stack 101 is disposed. In some embodiments, the semiconductor light-emitting stack 101 is made of AlₓIn₁₋ₓGaN, wherein 0≤x≤1. The semiconductor light-emitting stack 101 includes at least a first conductivity-type semiconductor layer 102, an active layer 103, and a second conductivity-type semiconductor layer 104, wherein the first conductivity-type semiconductor layer 102 and the second conductivity-type semiconductor layer 104 may respectively be an N-type semiconductor layer and a P-type semiconductor layer or vice versa. In addition, the semiconductor light-emitting stack 101 may be grown and formed on the substrate 100 by metal organic chemical vapor deposition (MOCVD), or may be formed by a transferring technique that can transfer the semiconductor light-emitting stack 101 onto the substrate 100.

The active layer 103 may include a plurality of quantum well layers and a plurality of quantum barrier layers alternately stacked. A primary function of the quantum well layers is to generate light via recombination of electrons and holes. Moreover, the quantum well layers may be made of, but is not limited to, indium gallium nitride (InGaN). Additionally, a major function of the quantum barrier layers is to constrain the recombination of electrons and holes within the quantum well layers. The quantum barrier layers may be made of, but is not limited to, gallium nitride (GaN). In addition, a main function of the above-mentioned N-type semiconductor layer is to provide electrons for electron-hole recombination, and the N-type semiconductor layer may be made of, but is not limited to, an N-type doped GaN. Furthermore, a main function of the foregoing P-type semiconductor layer is to provide holes for electron-hole recombination as described above, and the P-type semiconductor layer may be made of, but is not limited to, a P-type doped GaN.

The semiconductor light-emitting stack 101 may have a side surface, and the second conductivity-type semiconductor layer 104 has an upper surface. Light emitted from the active layer 103 may penetrate through the upper surface of the second conductivity-type semiconductor layer 104 and through the side surface of the semiconductor light-emitting stack 101 so as to be radiated out of the semiconductor light-emitting stack 101, thereby externally outputting the light.

The semiconductor light-emitting stack 101 may be formed with a recess extending downward from the second conductivity-type semiconductor layer 104 to the first conductivity-type semiconductor layer 102 so that the recess has a bottom surface exposing the first conductivity-type semiconductor layer 102, and a lateral surface extending from the bottom surface to the upper surface of the second conductivity-type semiconductor layer 104. The first electrode 105 is disposed on the bottom surface of the recess (i.e., on the first conductivity-type semiconductor layer 102). In addition, the transparent conductive layer 107 and the second electrode 106 are disposed on the second conductivity-type semiconductor layer 104. Specifically, the transparent conductive layer 107 and the second electrode 106 are both disposed on the upper surface of the second conductivity-type semiconductor layer 104. In addition, the insulating light-transmissive layer 109 covers an upper surface of the transparent conductive layer 107, the lateral surface of the recess, and the side surface of the semiconductor light-emitting stack 101.

A main function of the transparent conductive layer 107 is to form a good ohmic contact with the upper surface of the second conductivity-type semiconductor layer 104 and to enhance horizontal current spreading, thereby expanding the reach of current. In addition, the transparent conductive layer 107 may have a thickness ranging from 20 nm to 200 nm, and may have a refractive index ranging from 1.9 to 2.1. The transparent conductive layer 107 may be made of, for instance, indium tin oxide (ITO), zinc oxide (ZnO), or ITO doped with aluminum-silver alloy, and thus the transparent conductive layer 107 has a good electrical conductivity and light transmittance, and has a low manufacturing cost. In certain embodiments, the transparent conductive layer 107 occupies at least 80% of the upper surface of the second conductivity-type semiconductor layer 104. In an exemplary embodiment, the transparent conductive layer 107 occupies at least 90% of the upper surface of the second conductivity-type semiconductor layer 104.

The transparent conductive layer 107 may be formed using a coating technique. In addition, varying patterns may be formed as desired on the transparent conductive layer 107 using an etching technique. After coating, a high-temperature annealing treatment is conducted so as to achieve a good ohmic contact between an interface of the transparent conductive layer 107 and the second conductivity-type semiconductor layer 104.

A main function of the first electrode 105 and the second electrode 106 is to provide a connection with an external power source so as to permit an electric current from the external power source to be injected into the semiconductor light-emitting device. Each of the first electrode 105 and the second electrode 106 may include a plurality of metal layers successively laminated, which may sequentially be an ohmic contact layer (made of, e.g., chromium (Cr)), a reflective layer (made of, e.g., aluminum (Al)), a blocking layer (including at least one of a titanium (Ti) film, a platinum (Pt) film, and a chromium (Cr) film), and a wire bonding layer (mad of, e.g., at least one of gold (Au), Al, and copper (Cu)). A main function of the ohmic contact layer is to achieve an ohmic contact and offer adhesion between a metal material (e.g., the electrodes 105, 106) and a semiconductor material (e.g., the conductivity-type semiconductor layers 102, 104). Furthermore, the ohmic contact layer is thin in terms of thickness. In addition, a main function of the reflective layer is to reflect light emitted from the semiconductor light-emitting device so as to enhance the light emission efficiency of the semiconductor light-emitting device. The blocking layer may block diffusion of aluminum and may buffer wire bonding stress. Moreover, the wire bonding layer is primarily used for external wire bonding.

The semiconductor light-emitting device may further include a current blocking layer 108 disposed in a first position between the first electrode 105 and the first conductivity-type semiconductor layer 102 and/or a second position between the second electrode 106 and the second conductivity-type semiconductor layer 104. The current blocking layer 108 may be made of, but is not limited to, a transparent insulating material, e.g., silicon oxide. In addition, the current blocking layer 108 may be used to partially block current vertically spreading from one of the first and second electrodes 105, 106 to a corresponding one of the first and second conductivity-type semiconductor layers 102, 104. The current block layer 108 may be in the shape of a ring, a square, or a circle, and may contain one or more parts depending on the demand.

Each of the first electrode 105 and the second electrode 106 may include an electrode pad (i.e., a wired electrode 1061) which may be used for wire bonding, and at least one electrode line (i.e., an extending portion 1062). The electrode line is connected with the electrode pad and extends outward from the electrode pad. The electrode line of the second electrode 106 is formed on the transparent conductive layer 107, and is in direct contact with the transparent conductive layer 107 to facilitate horizontal current spreading so that current may be injected as much as possible into all areas within the second conductivity-type semiconductor layer 104, thereby improving the light emission efficiency of the semiconductor light-emitting device.

The insulating light-transmissive layer 109 may be an outermost layer of the semiconductor light-emitting device, and is disposed on a light-emitting surface of the semiconductor light-emitting stack 101. Specifically, the insulating light-transmissive layer 109 covers the lateral surface of the recess around the first electrode 105, the upper surface of the transparent conductive layer 107 around the second electrode 106, and the side surface of the semiconductor light-emitting stack 101. In certain embodiments, the insulating light-transmissive layer 109 has a refractive index which is lower than the refractive index of the transparent conductive layer 107, and a refractive index of the semiconductor light-emitting stack 101. The difference among the refractive indices of the semiconductor light-emitting stack 101, the transparent conductive layer 107, and the insulating light-transmissive layer 109 may help light emitted from the semiconductor light-emitting stack 101 to penetrate through the insulating light-transmissive layer 109 as much as possible after passing through the transparent conductive layer 107 or the side surface of the semiconductor light-emitting stack 101 and may lower reflectivity, thereby enhancing the light emission efficiency. The insulating light-transmissive layer 109 may also provide insulation and protection against moisture to the side surface of the semiconductor light-emitting stack 101 and the transparent conductive layer 107 around the electrode 106.

In order to improve light transmittance of the insulating light-transmissive layer 109 for light emitted from the active layer 103, this disclosure optimizes the insulating light-transmissive layer 109 such that the insulating light-transmissive layer 109 may include at least a graded index structure including at least two films 1091, 1092, and having a gradually varying refractive index which gradually decreases from inside to outside so as to reduce the refractive index difference between any of the adjacent films of the at least two films 1091, 1092, thereby enhancing light transmittance and reducing light reflectance. In some embodiments, the gradually varying refractive index of the graded index structure is not less than 1.6.

In certain embodiments, the at least two films 1091, 1092 include a first film 1091 and a second film 1092. In yet another exemplary embodiment, the refractive index of the first film 1091 is greater than the refractive index of the second film 1092. In addition, the first film 1091 may be closer to the transparent conductive layer 107 or the side surface of the semiconductor light-emitting stack 101 than the second film 1092. In other embodiments, the second film 1092 is an outermost film of the graded index structure.

In yet other embodiments, the difference between the refractive indices of the first and second films 1091, 1092 is not greater than 0.3. In certain embodiments, the refractive index of the first films 1091 ranges from 1.8 to 1.95. Since the second film 1092 may be the outermost layer of the semiconductor light-emitting device, the refractive index of an outside medium that is in contact with the insulating light-transmissive layer 109 needs to be taken into consideration. To illustrate this point, the semiconductor light-emitting device is typically encapsulated with a sealing resin 304 (see FIG. 4). Hence, in certain embodiments, the refractive index of the second film 1092 of the graded index structure is greater than a refractive index of the sealing resin 304. For example, the refractive index of the second film 1092 may be at least 1.6. In an exemplary embodiment, the difference between the refractive indices of the second film 1092 and the sealing resin 304 is not greater than 0.3. In another exemplary embodiment, the refractive index of the second film 1092 ranges from 1.6 to 1.75.

The semiconductor light-emitting device may further include at least one refractive index transitional layer disposed between the first film 1091 and the second film 1092. The at least one refractive index transitional layer has a refractive index ranging between the refractive index of the first film 1901 and the refractive index of the second film 1092.

In certain embodiments, the graded index structure is made of an insulating transparent material selected from an inorganic compound. In other embodiments, for example, the first film 1091 is a nitrogen-containing film (such as an oxynitride film or a nitride film), or an oxide film. In yet other embodiments, the first film 1091 is made of a material selected from silicon nitride and silicon oxynitride. Moreover, in an exemplary embodiment, the second film 1092 of the graded index structure is an oxynitride film or an oxide film. In another exemplary embodiment, the second film 1092 is made of a material selected from silicon oxynitride and aluminum oxide. In this embodiment, the first film 1091 of the graded index structure of the insulating light-transmissive layer 109 is made of silicon nitride or zirconium oxide, and the second film 1092 of the graded index structure is made of silicon oxynitride or aluminum oxide. Plasma-enhanced chemical vapor deposition (PECVD) or atomic layer deposition (ALD) may be employed to form any one film of the graded index structure and/or the insulating light-transmissive layer 109.

In certain embodiments, the first film 1091 of the graded index structure of the insulating light-transmissive layer 109 has a thickness ranging from 10 nm to 300 nm. In certain embodiments, the second film 1092 of the graded index structure of the insulating light-transmissive layer 109 has a thickness ranging from 10 nm to 300 nm.

In an exemplary embodiment, the graded index structure consists of the first film 1091 and the second film 1092. Moreover, in another exemplary embodiment, the first film 1091 and the second film 1092 are respectively made of silicon nitride and silicon oxide. The first film 1091 and the second film 1092 may be obtained using the same process (e.g., in a PECVD process, the first and second films 1091, 1092 may be subsequently formed in a single chamber using different gas sources). In addition, the gas sources for silicon nitride may be ammonia, silane, and nitrogen gas. In some other embodiments, the first film 1091 may be formed using a PECVD process, and the second film 1092 may be formed using an ALD process.

The insulating light-transmissive layer 109 may be attached to the transparent conductive layer 107 (i.e., in certain embodiments, the transparent conductive layer 107 is disposed between the insulating light-transmissive layer 109 and at least a portion of the light-emitting surface, and the refractive index of the transparent conductive layer 107 is greater than the gradually varying refractive index), forming multilayers having a gradually decreasing refractive index from the transparent conductive layer 107 to the outermost layer of the insulating light-transmissive layer 109, which may improve the enhancement of light extraction. Since the transparent conductive layer 107 (in particular for which is made of ITO, ITO doped with aluminum, ITO doped with silver, or ITP doped with aluminum-silver alloy) has an active nature, a surface of the transparent conductive layer 107 is prone to lead to a chemical reaction caused by an acidic or a basic compound. Thus, the insulating light-transmissive layer 109 further includes a base 1090. The base 1090 is disposed between the first film 1091 of the graded index structure and the transparent conductive layer 107 so as to prevent the first film 1091 from directly adhering to the transparent conductive layer 107. If the first film 1091 directly adheres to the transparent conductive layer 107 during deposition of the first film 1091 (for example, using the PECVD process), a by-product that absorbs light may be undesirably formed on the surface of the transparent conductive layer 107, resulting in a decrease in light transmission. Meanwhile, disposing the base 1090 between the first film 1091 and the transparent conductive layer 107 may also prevent a reduction of switch voltage (VF4) of the semiconductor light-emitting device, thereby eliminating current leakage in the semiconductor light-emitting device. For example, in the case where the first and second films 1091, 1902 are obtained using a PECVD technique, especially when the first film 1091 is a nitrogen-containing film and the base 1090 is a nitrogen-free film, the reduction of the VF4 may be effectively prevented. For instance, the base 1090 is an oxide film, such as a silicon oxide film. In an exemplary embodiment, the base 1090 is manufactured using the same technique as of the graded index structure. When the base 1090 is made of silicon oxide, a refractive index of the base 1090 is lower than the gradually varying refractive index of the graded index structure. The refractive index of silicon oxide is lower than 1.5, and specifically, is approximately 1.48. For the base 1090 having a lower refractive index, in certain embodiments, the base 1090 has a thickness ranging from 10 nm to 80 nm. If the thickness of the base 1090 exceeds the above-mentioned range, light transmission will decrease and light reflectance will increase, which may consequently lead to a reduced light emission efficiency.

The insulating light-transmissive layer 109 according to the disclosure covers the transparent conductive layer 107 and the side surface of the semiconductor light-emitting stack 101. On the one hand, the graded index structure of the insulating light-transmissive layer 109 is a multi-film structure that has the gradually varying refractive index which gradually decrease in a direction from a film closer to the transparent conductive layer 107 to a film farther away from the transparent conductive layer 107, and the gradually varying refractive index of the graded index structure is lower than the refractive index of the transparent conductive layer 107, which may effectively prevent a great change in refractive index of a conventional semiconductor light-emitting device (to which light emitted from the active layer of the semiconductor light-emitting stack is directly transmitted to a conventional silicon dioxide layer (with a refractive index of approximately 1.44) serving as a sealing resin). As such, the provision of the insulating light-transmissive layer 109 can reduce reflection of light that emitted from the active layer 103 occurring at an interface between the insulating light-transmissive layer 109 and the light-emitting surface of the semiconductor light-emitting stack 101. Therefore, light loss occurred in the path of transmission may be reduced, so that the light emission efficiency of the semiconductor light-emitting device may be enhanced. In the meantime, due to the reduction of light loss, heat generated by the light loss may also be reduced so that a rise in temperature may be avoided, thereby extending the service life of the semiconductor light-emitting device. On the other hand, to ensure that the insulating light-transmissive layer 109 does not adversely affect the light transmission of the transparent conductive layer 107 and the switch voltage (VF4) of the semiconductor light-emitting device, the insulating light-transmissive layer 109 of the present disclosure further includes the base 1090. The base 1090 may effectively protect the transparent conductive layer 107 by preventing a surface of the transparent conductive layer 107 from being damaged by a raw material used in the manufacturing of the graded index structure so as to avoid a reduced light transmittance. In an exemplary embodiment, when the first film 1091 of the graded index structure is a nitrogen-containing film, the base 1090 is a nitrogen-free film, such as a silicon oxide film. Since in the above-mentioned embodiment, the difference between the refractive index of the base 1090 and the refractive index of the transparent conductive layer 107 is greater, the base 1090 has a thickness not greater than 80 nm.

According to another aspect of the disclosure, a method for manufacturing a face-up type semiconductor light-emitting device is provided, which is suitable for manufacturing the semiconductor light-emitting device as shown in FIGS. 1 to 2, and which includes the steps as described below.

In step 1, an N-type semiconductor layer (i.e., the first conductivity-type semiconductor layer 102), the active layer 103, and a P-type semiconductor layer (i.e., the second conductivity-type semiconductor layer 104) are sequentially formed on the substrate 100. The substrate 100 may be a sapphire substrate. Specifically, the N-type semiconductor layer, the active layer 103, and the P-type semiconductor layer may be sequentially grown on the substrate 100 by using metal organic chemical vapor deposition (MOCVD).

In addition, before growing the N-type semiconductor layer on the substrate 100, a buffer layer (not shown), such as a gallium nitride layer, may be grown in advance.

In step 2, the recess extending from the P-type semiconductor layer to the N-type semiconductor layer is formed so that the bottom surface of the recess is formed on the N-type semiconductor layer.

The recess may be formed using a photomask in combination with dry etching.

In step 3, the transparent conductive layer 107 is formed on the P-type semiconductor layer.

First, the transparent conductive layer 107 may be formed on the P-type semiconductor layer and both the bottom surface and the lateral surface of the recess using a magnetron sputtering technique. Afterwards, photomask in combination with dry etching are employed to remove portions of the transparent conductive layer 107 at the bottom surface and the lateral surface of the recess.

The transparent conductive layer 107 formed by using the magnetron sputtering technique may have a higher density and good current spreading, so the semiconductor light-emitting device with the foregoing transparent conductive layer 107 may have a lower turn-on voltage.

In an exemplary embodiment, the current blocking layer 108 is formed on the P-type semiconductor layer and/or on the N-type semiconductor layer prior to forming the transparent conductive layer 107.

In step 4, a P-type electrode (i.e., the second electrode 106) and an N-type electrode (i.e., the first electrode 105) are respectively disposed on the P-type semiconductor layer and the N-type semiconductor layer exposing through the recess. In addition, each of the N-type electrode and the P-type electrode may include the electrode pad and the electrode line.

The N-type electrode may be in partial or total contact with the N-type semiconductor layer. Moreover, a portion of the P-type electrode may be in contact with the P-type semiconductor layer, another portion of the P-type electrode may be in contact with the current blocking layer 108, and a remaining portion of the P-type electrode may be in contact with the transparent conductive layer 107.

In step 5, the insulating light-transmissive layer 109 is formed on the N-electrode in the recess, on the lateral surface of the recess, on the transparent conductive layer 107, and on the side surface of the semiconductor light-emitting stack 101. After that, the photomask technique combined with etching is used to expose at least a part of a top surface of each of the N-type electrode and the P-type electrode.

In this embodiment, the insulating light-transmissive layer 109 includes the base 1090, and the first film 1091 and the second film 1092 of the graded index structure.

Additionally, the base 1090 may be made of silicon oxide. The first film 1091 of the graded index structure may be made of silicon nitride. The second film 1092 of the graded index structure may be made of aluminum oxide. Each of the base 1090, the first film 1091, and the second film 1092 may be manufactured using the PECVD technique or the ALD technique. The gas source of silicon oxide is silane, nitrous oxide, and nitrogen gas. The gas source of silicon nitride is ammonia, silane, and nitrogen gas. In addition, the aluminum oxide is deposited using ion-beam assisted deposition (IBAD), and the raw material used is aluminum oxide. In addition, aluminum oxide may also be obtained using the ALD technique in which trimethylaluminum and water/ozone are used.

In certain embodiments, the base 1090 has a thickness ranging from 10 nm to 80 nm. In certain embodiments, the first film 1091 has a thickness ranging from 10 nm to 300 nm, and the second film 1092 has a thickness ranging from 10 nm to 300 nm.

The method in this embodiment may further include: thinning the substrate 100; forming the reflective layer (not shown) on the second surface 1002 of the substrate 100 (i.e., for the substrate 100, the surface 1002 on which the reflective layer is formed is opposite to the surface 1001 on which the semiconductor light-emitting stack 101 is formed); and finally performing scribing and splitting so as to obtain at least two of the semiconductor light-emitting devices.

Referring to FIG. 4, in this embodiment, a sealing package is obtained by sealing the semiconductor light-emitting device mentioned above. The sealing package includes a packaging substrate 300, the semiconductor light-emitting device, and the sealing resin 304.

The packaging substrate 300 may include a mounting region 303, and two electrode connection areas 301, 302. The packaging substrate 300 may be a planar substrate or a cup-shaped substrate.

The sealing resin 304 may cover the light-emitting surface of the semiconductor light-emitting stack 101, and the sealing resin 304 may be in contact with the insulating light-transmissive layer 109. The sealing resin 304 has a refractive index lower than a refractive index of the outermost film 1092 of the insulating light-transmissive layer 109 of the semiconductor light-emitting device, so that a relatively great change in refractive index may be avoided when light emitted from the semiconductor light-emitting stack 101 penetrates the insulating light-transmissive layer 109 to reach a surface of the seal resin 304. Therefore, the light emission efficiency of the semiconductor light-emitting device may be further enhanced while preventing heat from being generated due to the light loss. The rising temperature that may affect the service life of the semiconductor light-emitting device may also be avoided.

In other embodiments, the sealing resin 304 has a refractive index ranging from 1.4 to 1.55. In an exemplary embodiment, the sealing resin 304 is an organic silicone resin.

The semiconductor light-emitting device manufactured by the above-mentioned method according to the present disclosure was subjected to a light emission efficiency test and a switch voltage (VF4) test, and then the results were compared with the conventional semiconductor light-emitting device. Referring to Table 1, the ratio of brightness enhancement and the value of switch voltage (VF4) enhancement were calculated by comparing brightness and the switch voltage (VF4) of the semiconductor light-emitting device of the present disclosure against those of the conventional semiconductor light-emitting device (in which a single layer of silicon oxide is used as an insulating light-transmissive layer). In this embodiment, the conditions for manufacturing the semiconductor light-emitting device were substantially the same as those of the conventional light-emitting device, except for of the insulating light-transmissive layer 109. In Table 1, the insulating light-transmissive layer 109 of the semiconductor light-emitting device of this embodiment had three layers (i.e., the base 1090 made of silicon oxide, the first film 1091 made of silicon nitride, and the second film 1092 made of aluminum oxide). In addition, the insulating light-transmissive layer of the conventional semiconductor light-emitting device was made of silicon oxide. After the semiconductor light-emitting device of this embodiment and the conventional semiconductor light-emitting device were sealed with an organic silicone resin, brightness tests were conducted.

Referring to Table 1, the brightness of the semiconductor light-emitting device of this embodiment before sealing was 0.9% greater than that of the conventional semiconductor light-emitting device. After sealing with the organic silicone resin, the brightness of the semiconductor light-emitting device of this embodiment was 3.1% greater than that of the conventional semiconductor light-emitting device. For the semiconductor light-emitting device not sealed with the sealing resin 304, light emitted from the insulating light-transmissive layer 109 may directly enter air. Due to a greater difference in refractive index between the air and the insulating light-transmissive layer 109, partial light loss may occur owing to reflection before light enters the air, resulting in the brightness enhancement being insignificant. However, for the semiconductor light-emitting device sealed with the sealing resin 304 which had a refractive index less than that of the insulating light-transmissive layer 109, the light may firstly pass through the insulating light-transmissive layer 109 and the sealing resin 304 and then enter the air. In such circumstance, the sealing resin 304 serves as a refractive index transition layer so as to enhance a direct light output, thereby reducing light reflectance and improving the final light emission efficiency. Furthermore, the switch voltage (VF4) is also enhanced.

TABLE 1

| | Brightness | Brightness | Value of switch |
|---|---|---|---|
| | enhancement ratio | enhancement ratio | voltage |
| | before sealing | after sealing | enhancement (VF4) |
| Example 1 | 0.9% | 3.1% | 0.005 V |
| Comparative | −9.45% | −4.01% | −0.170 V |
| Example 1 | | | |
| Comparative | −0.03% | 0.43% | 0.001 V |
| Example 2 | | | |

### Comparative Example 1

A semiconductor light-emitting device of Comparative Example 1 example, unlike that in Example 1, had an insulating light-transmissive layer which included only the first film 1091 and the second film 1092 (i.e., the base 1090 was not included herein). As shown in Table 1, the semiconductor light-emitting device of Comparative Example 1 before sealing had a brightness enhancement ratio of −9.54% compared to that of the conventional semiconductor light-emitting device. After sealing with the organic silicone resin, the semiconductor light-emitting device of Comparative Example 1 had a brightness enhancement ratio of −4.04%. Moreover, the switch voltage (VF4) of Comparative Example 1 was reduced by 0.170V. It can be seen that that the base 1090 may effectively improve light transmittance of the transparent conductive layer 107, thereby enhancing the brightness and boosting the switch voltage (VF4) of the semiconductor light-emitting device.

### Comparative Example 2

A semiconductor light-emitting device in Comparative Example 2, unlike that in the Comparative Example 1, had an insulating light-transmissive layer which included only the second film 1092 (i.e., the base 1090 and the first film 1091 were not included herein). The second film 1092 is made of aluminum oxide. As shown in Table 1, the semiconductor light-emitting device of Comparative Example 2 before sealing had a brightness enhancement ratio of −0.03%. After sealing with the organic silicone resin, the semiconductor light-emitting device of Comparative Example 2 had a brightness enhancement ratio of 0.43%.

In sum, the reliability of the semiconductor light-emitting device of the present disclosure may be enhanced by encapsulating with the sealing resin to make into, for example, a package, by improving the insulating light-transmissive layer 109 of the semiconductor light-emitting device, by enhancing the light transmittance of the sealing resin employed, and/or by increasing the switch voltage (VF4) at a small current.

The package of the present disclosure may further be turned into other light-emitting appliances, such as a white lighting device, a backlight display device, a red-green-blue (RGB) display device, a vehicle light, a flash light, a projection apparatus, a stage light, an ultraviolet sterilization lamp, or a filament lamp.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor light-emitting device, comprising:
a semiconductor light-emitting stack; and
an insulating light-transmissive layer disposed on said semiconductor light-emitting stack, and including
a base having a first refractive index, and
a graded index structure disposed on said base in a way that said base is disposed between said semiconductor light-emitting stack and said graded index structure, said graded index structure including at least two films, said at least two films including a first film that is adjacent to said base, and a second film that is disposed in a position most remote from said base, a refractive index of said first film being greater than a refractive index of said second film; and
a transparent conductive layer disposed on said semiconductor light-emitting stack,
wherein said first refractive index of said base is lower than a refractive index of said transparent conductive layer and a refractive index of said semiconductor light-emitting stack.

2. The semiconductor light-emitting device as claimed in claim 1, wherein said transparent conductive layer is directly disposed on said semiconductor light-emitting stack.

3. The semiconductor light-emitting device as claimed in claim 1, further comprising a first electrode and a second electrode, said first electrode being disposed on a first conductivity-type semiconductor layer of said semiconductor light-emitting stack, said transparent conductive layer and said second electrode being disposed on a second conductivity-type semiconductor layer of said semiconductor light-emitting stack.

4. The semiconductor light-emitting device as claimed in claim 1, wherein said transparent conductive layer has a thickness ranging from 20 nm to 200 nm.

5. The semiconductor light-emitting device as claimed in claim 3, wherein said second electrode includes an electrode pad which is used for wire bonding, and at least one electrode line.

6. The semiconductor light-emitting device as claimed in claim 5, wherein said at least one electrode line is connected to said electrode pad and extends outward from said electrode pad.

7. The semiconductor light-emitting device as claimed in claim 5, wherein said at least one electrode line of said second electrode is formed on said transparent conductive layer, and is in direct contact with said transparent conductive layer.

8. The semiconductor light-emitting device as claimed in claim 5, wherein said insulating light-transmissive layer covers an upper surface of said transparent conductive layer exposed from said at least one electrode line of said second electrode, an upper surface of said electrode line, and a side surface of said semiconductor light-emitting stack.

9. The semiconductor light-emitting device as claimed in claim 1, wherein said refractive index of said first film is greater than said first refractive index of said base.

10. The semiconductor light-emitting device as claimed in claim 1, wherein each of said refractive index of said first film and said refractive index of said second film is greater than said first refractive index of said base.

11. The semiconductor light-emitting device as claimed in claim 1, wherein a refractive index of said graded index structure is greater than said first refractive index of said base.

12. The semiconductor light-emitting device as claimed in claim 1, wherein a refractive index of said graded index structure is not less than 1.6.

13. The semiconductor light-emitting device as claimed in claim 1, wherein said semiconductor light-emitting stack includes an active layer and has a light-emitting surface, said insulating light-transmissive layer being disposed on said light-emitting surface.

14. The semiconductor light-emitting device as claimed in claim 1, wherein said graded index structure is made of an insulating transparent material selected from an inorganic compound.

15. The semiconductor light-emitting device as claimed in claim 1, wherein said base is a nitrogen-free film.

16. The semiconductor light-emitting device as claimed in claim 1, wherein said base has a thickness ranging from 10 nm to 80 nm.

17. The semiconductor light-emitting device as claimed in claim 1, wherein said first film is a nitrogen-containing film.

18. The semiconductor light-emitting device as claimed in claim 17, wherein said first film is made of silicon nitride, and said second film is made of a material selected from silicon oxynitride and aluminum oxide.

19. The semiconductor light-emitting device as claimed in claim 1, wherein said first film has a thickness ranging from 10 nm to 300 nm, and said second film has a thickness ranging from 10 nm to 300 nm.

20. The semiconductor light-emitting device as claimed in claim 1, wherein said semiconductor light-emitting stack is made of AlₓIn₁₋ₓGaN, wherein 0≤x≤1.
